(19) United States
(12) Patent Application Publication
(10) Pub. No.: US 2019/0243348 A1
(43) Pub. Date: Aug. 8, 2019

(54) DATA PROCESSING METHOD, DATA PROCESSING APPARATUS, DATA PROCESSING SYSTEM, AND RECORDING MEDIUM HAVING RECORDED THEREIN DATA PROCESSING PROGRAM

(71) Applicant: SCREEN Holdings Co., Ltd., Kyoto (JP)

(72) Inventors: Hideji NAOHARA, Kyoto-shi (JP); Kouhei NISHIKAWA, Kyoto-shi (JP)

(21) Appl. No.: 16/261,789

(22) Filed: Jan. 30, 2019

(30) Foreign Application Priority Data
Feb. 8, 2018 (JP) 2018-020799

(51) Int. Cl. G05B 19/418; H01L 21/67

(52) U.S. Cl. CPC G05B 19/41875; G05B 2219/45031; H01L 21/67276

(57) ABSTRACT

A data processing method for processing a plurality of pieces of unit-processing data (each unit-processing data includes a plurality of pieces of time series data) includes: a unit-processing data evaluating step of taking, as reference data, previously defined unit-processing data among the plurality of pieces of unit-processing data and calculating an evaluation value for unit-processing data to be evaluated based on the unit-processing data to be evaluated and the reference data; and a reference data changing step of changing the reference data based on the evaluation value calculated in the unit-processing data evaluating step.

### BACKGROUND OF THE INVENTION

### Field of the Invention

The present invention relates to digital data processing, and particularly relates to a method for processing time series data.

### Description of Related Art

As a method for detecting an abnormality of equipment or an apparatus, there is known a method of measuring a physical quantity (e.g., length, angle, time, speed, force, pressure, voltage, current, temperature, flow rate, etc.) which shows an operation state of the equipment or the apparatus by use of a sensor or the like, and analyzing time series data obtained by arranging measurement results in order of occurrence. When the equipment or the apparatus performs the same operation in the same condition, if there is no abnormality, the time series data changes in the same way. Therefore, by comparing a plurality of pieces of time series data which change in the same way to each other to detect abnormal time series data and analyzing the abnormal time series data, it is possible to specify a place where the abnormality occurs and the cause of the abnormality. Also, in recent years, computer data processing capability has been improved remarkably. There have thus been many cases where, even when an amount of data is enormous, necessary results can be obtained in practical time. This also shows that the analysis of time series data is becoming active.

For example, in a semiconductor manufacturing apparatus, time series data can be obtained in various processes. Therefore, also in the field of the semiconductor manufacturing apparatus, analysis of time series data, display of time series data on a screen, and the like, have been performed.

In connection with the present invention, Japanese Laid-Open Patent Publication No. 2017-83985 discloses an invention of a time series data processing apparatus that displays time series data in a mode easy for the user to analyze. In the time series data processing apparatus, a plurality of pieces of time series data are divided into a plurality of groups, and an abnormality degree of each group and an abnormality degree of time series data within each group are calculated. Then, a result of ranking the groups or the pieces of time series data based on the abnormality degrees is displayed on a display.

A substrate processing apparatus such as a cleaning apparatus, which is one type of the semiconductor manufacturing apparatus, generally includes a plurality of chambers (processing chambers). When the same recipe is executed in the plurality of chambers, uniform results are preferably obtained in the plurality of chambers. Hence a plurality of chambers included in one substrate processing apparatus preferably have similar processing performance. However, in reality, a difference in processing performance occurs among a plurality of chambers. For this reason, when processing is being normally performed on a substrate in a certain chamber, similar processing may not be being normally performed in another chamber.

In view of this, also in the field of substrate processing apparatuses, analysis of time series data obtained by various processes is being performed in order to achieve early detection of abnormality and prevention of abnormality. Meanwhile, in order to determine whether or not each piece of time series data included in a plurality of pieces of time series data changing in the same manner is abnormal, each piece of time series data to be evaluated is compared with time series data having ideal time-series values (data values). As time series data having the ideal time series values, for example, it is conceivable to use time series data made up of average values of a plurality of pieces of time series data. However, in a case where the plurality of pieces of time series data on which an average value is calculated include a large number of pieces of data having abnormal values or having significantly different values from the other values, a calculated average value is not necessarily an ideal value, and an abnormality thus cannot be detected accurately.

### SUMMARY OF THE INVENTION

An object of the present invention is therefore to provide a data processing method capable of performing abnormality detection using time series data more accurately than before.

One aspect of the present invention is directed to a data processing method for processing a plurality of pieces of unit-processing data by regarding a plurality of time series data obtained by unit-processing as unit-processing data, the method including:

a unit-processing data evaluating step of taking, as reference data, previously defined unit-processing data among the plurality of pieces of unit-processing data and calculating an evaluation value for unit-processing data to be evaluated based on the unit-processing data to be evaluated and the reference data; and

a reference data changing step of changing the reference data based on the evaluation value calculated in the unit-processing data evaluating step.

With such a configuration, an evaluation value is calculated for each piece of unit-processing data which is a group of pieces of time series data obtained by the unit-processing. At that time, the evaluation value is calculated based on the unit-processing data to be evaluated and the reference data previously defined. Therefore, the magnitude of the degree of similarity between the unit-processing data to be evaluated and the reference data can be reflected to the evaluation value of the unit-processing data to be evaluated. Then, since the reference data is changed based on the evaluation value, unit-processing data having a high degree of similarity to the reference data before change can be defined as the reference data after change. Since the reference data is preferably defined in this way, by comparing the time series data included in each piece of unit-processing data with the time series data included in the reference data, it is possible to accurately detect an abnormality in the processing. As described above, it is possible to perform the abnormality detection using time series data more accurately than before.

Another aspect of the present invention is directed to a data processing apparatus for processing a plurality of pieces of unit-processing data by regarding a plurality of pieces of time series data obtained by unit-processing as unit-processing data, the apparatus including:

a unit-processing data evaluation part configured to take, as reference data, previously defined unit-processing data among the plurality of pieces of unit-processing data and calculate an evaluation value for unit-processing data to be evaluated based on the unit-processing data to be evaluated and the reference data; and

a reference data changing part configured to change the reference data based on the evaluation value calculated in the unit-processing data evaluation part.

Still another aspect of the present invention is directed to a data processing system for processing a plurality of pieces of unit-processing data by regarding a plurality of pieces of time series data obtained by unit-processing as unit-processing data, the system including:

a unit-processing data evaluation part configured to take, as reference data, previously defined unit-processing data among the plurality of pieces of unit-processing data and calculates an evaluation value for unit-processing data to be evaluated based on the unit-processing data to be evaluated and the reference data; and

a reference data changing part configured to change the reference data based on the evaluation value calculated in the unit-processing data evaluation part.

Still another aspect of the present invention is directed to a computer-readable recording medium having recorded therein a data processing program for processing a plurality of pieces of unit-processing data by regarding a plurality of time series data obtained by unit-processing as unit-processing data, wherein the data processing program causes a computer to execute:

a unit-processing data evaluating step of taking, as reference data, previously defined unit-processing data among the plurality of pieces of unit-processing data and calculating an evaluation value for unit-processing data to be evaluated based on the unit-processing data to be evaluated and the reference data; and

a reference data changing step of changing the reference data based on the evaluation value calculated in the unit-processing data evaluating step.

These and other objects, features, modes, and advantages of the present invention will become more apparent from the following detailed description of the present invention with reference to the accompanying drawings.

### BRIEF DESCRIPTION OF THE DRAWINGS

FIG. 1 is a diagram showing a schematic configuration of a substrate processing apparatus according to an embodiment of the present invention.

FIG. 2 is a diagram representing a certain time series data by a graph.

FIG. 3 is a diagram for explaining unit-processing data in the embodiment.

FIG. 4 is a block diagram showing a hardware configuration of a controller of the substrate processing apparatus in the embodiment.

FIG. 5 is a diagram for explaining time series data DB in the embodiment.

FIG. 6 is a diagram for explaining reference data DB in the embodiment.

FIG. 7 is a flowchart showing a procedure of data processing concerning the change in the reference data in the embodiment.

FIG. 8 is a view showing an example of a scoring screen in the embodiment.

FIG. 9 is a view showing an example of a scoring result list screen in the embodiment.

FIG. 10 is a view for explaining transition of the scoring result list screen at the time of recommendation setting in the embodiment.

FIG. 11 is a view for explaining the transition of the scoring result list screen at the time of recommendation setting in the embodiment.

FIG. 12 is a view showing an example of a ranking setting screen in the embodiment.

FIG. 13 is a view showing an example of the ranking screen in the embodiment.

FIG. 14 is a view for explaining transition of the ranking screen at the time when reference data is changed in the embodiment.

FIG. 15 is a flowchart showing a procedure of data processing concerning the change in the reference data in the first modified example of the embodiment.

FIG. 16 is a flowchart showing a procedure of data processing concerning the change in the reference data in the second modified example of the embodiment.

FIG. 17 is a view showing an example of a ranking setting screen in the third modified example of the embodiment.

FIG. 18 is a view showing an example of a scoring result list screen in the fourth modified example of the embodiment.

FIG. 19 is a view showing an example of a data value input screen in the fourth modified example of the embodiment.

FIG. 20 is a view showing an example of a ranking setting screen in the fourth modified example of the embodiment.

FIG. 21 is a diagram for explaining calculation of the direct comparison value in the fifth modified example of the embodiment.

FIG. 22 is a view showing an example of a screen for setting the influence degree for each evaluation item in the fifth modified example of the embodiment.

FIG. 23 is a view showing an example of a reference data history screen in the sixth modified example of the embodiment.

FIG. 24 is a view showing an example of a period specification screen in the sixth modified example of the embodiment.

FIG. 25 is a view showing an example of a chamber ranking screen in the seventh modified example of the embodiment.

FIG. 26 is a view showing an example of a recipe ranking screen in the seventh modified example of the embodiment.

### DETAILED DESCRIPTION OF PREFERRED EMBODIMENTS

A preferred embodiment of the present invention will be described below with reference to the drawings.

### 1. CONFIGURATION OF SUBSTRATE PROCESSING APPARATUS

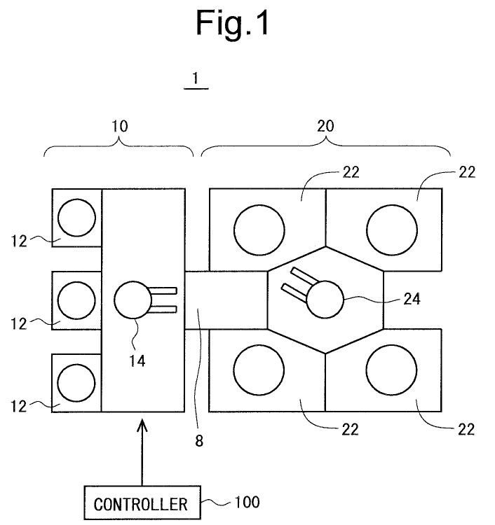

FIG. 1 is a diagram showing a schematic configuration of a substrate processing apparatus 1 according to a embodiment of the present invention. The substrate processing apparatus 1 includes an indexer part 10 and a processing part 20. The indexer part 10 includes a plurality of substrate container holding parts 12 for placing a substrate container (cassette) capable of accommodating a plurality of substrates, and an indexer robot 14 for carrying a substrate out of the substrate container and carrying a substrate into the substrate container. The processing part 20 includes a plurality of processing units 22 for performing processing such as cleaning of substrates using a processing liquid, and a substrate transfer robot 24 for carrying a substrate into the processing unit 22 and carrying a substrate out of the processing unit 22. The number of processing units 22 is, for example, 12. In this case, for example, a tower structure formed by laminating three processing units 22 is provided at each of four positions around the substrate transfer robot 24 as shown in FIG. 1. Each processing unit is provided with a chamber that is a space for processing the substrate, and the processing liquid is supplied to the substrate in the chamber. Further, the substrate processing apparatus 1 is internally provided with a controller 100 constituted of a microcomputer.

When processing is performed on the substrate, the indexer robot 14 takes the substrate to be processed out of the substrate container placed on the substrate container holding part 12 and transfers the substrate to the substrate transfer robot 24 via a substrate transfer part 8. The substrate transfer robot 24 carries the substrate received from the indexer robot 14 into the target processing unit 22. When the processing on the substrate is completed, the substrate transfer robot 24 takes the substrate out of the target processing unit 22 and transfers the substrate to the indexer robot 14 via the substrate transfer part 8. The indexer robot 14 carries the substrate received from the substrate transfer robot 24 to a target substrate container.

The controller 100 controls operation of an object to be controlled (such as a moving mechanism for moving the indexer robot 14) included in the indexer part 10 and the processing part 20. In addition, the controller 100 accumulates and holds time series data obtained by executing a recipe in this substrate processing apparatus 1, and performs various pieces of data processing using the time series data.

### 2. TIME SERIES DATA

In the substrate processing apparatus 1 according to the present embodiment, time series data is acquired every time a recipe is executed in order to detect abnormality of equipment relating to processing in each processing unit 22, abnormality of processing performed in each processing unit 22, and the like. The time series data acquired in the present embodiment is obtained by measuring various physical quantities (e.g., a flow rate of a nozzle, an internal pressure of a chamber, an exhaust pressure of a chamber, etc.) using a sensor or the like when a recipe is executed, and arranging measurement results in chronological order. In a data processing program to be described later, various physical quantities are processed as values of corresponding parameters, respectively. Note that one parameter corresponds to one type of physical quantity.

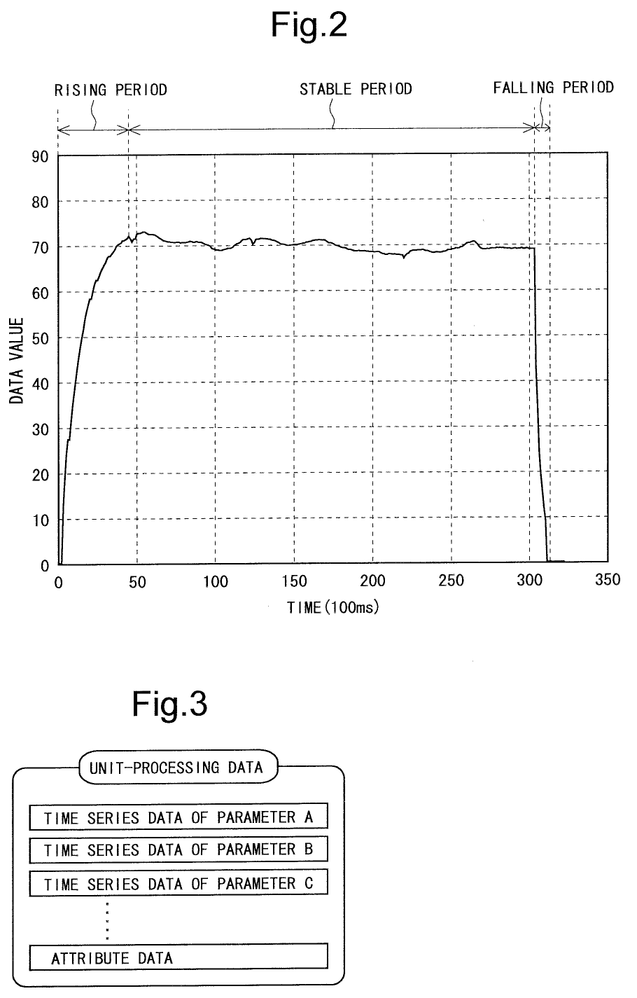

FIG. 2 is a diagram representing a certain time series data by a graph. This time series data is data on a certain physical quantity obtained by processing on one substrate in a chamber in one processing unit 22 when one recipe is executed. Note that, although the time series data is data made up of a plurality of discrete values, two temporally adjacent data values are connected by a straight line in FIG. 2. Meanwhile, when one recipe is executed, time series data on various physical quantities are obtained for each processing unit 22 in which the recipe is executed. Therefore, hereinafter, processing which is performed on one substrate in the chamber in one processing unit 22 when one recipe is executed is referred to as “unit-processing”, and a group of time series data obtained by the unit-processing is called “unit-processing data.” As schematically shown in FIG. 3, one piece of unit-processing data includes time series data on a plurality of parameters and attribute data made up of data on a plurality of items (e.g., processing start time, processing end time, etc.) for specifying the piece of unit-processing data. As for FIG. 3, “parameter A”, “parameter B”, and “parameter C” correspond to different kinds of physical quantities.

For detecting an abnormality in equipment or processing, unit-processing data obtained by executing a recipe should be compared with unit-processing data having an ideal data value as a processing result. More specifically, a plurality of pieces of time series data included in unit-processing data obtained by executing a recipe should be compared with a plurality of pieces of time series data included in unit-processing data each having an ideal data value as a processing result. Therefore, in the present embodiment, unit-processing data for comparison with unit-processing data to be evaluated (unit-processing data made up of a plurality of pieces of time series data for comparison with a plurality of pieces of time series data included in the unit-processing data to be evaluated) is defined as reference data for each recipe.

Note that, in the present embodiment, in one substrate processing apparatus 1, the reference data is defined for each recipe regardless of the number of the processing unit 22 (the number of the chamber). However, the present invention is not limited thereto. The reference data may be defined for each recipe and for each processing unit 22 (that is, for each processing unit 22 regarding each recipe). In addition, for example, in a case in which a plurality of substrate processing apparatuses 1 of the same type is installed in one factory, one common reference data for the plurality of substrate processing apparatuses 1 may be defined for each recipe (that is, it is possible to implement the present invention in a mode of the data processing system including the plurality of substrate processing apparatuses 1). In this case, the unit-processing data obtained by the specific substrate processing apparatuses 1 may be defined as the reference data, and the unit-processing data obtained by any substrate processing apparatuses 1 may be defined as the reference data.

### 3. CONFIGURATION OF CONTROLLER

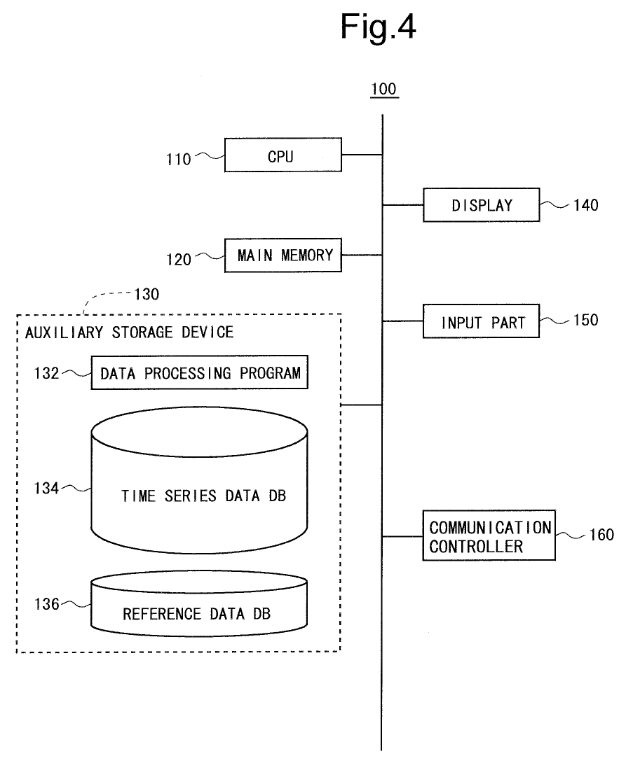

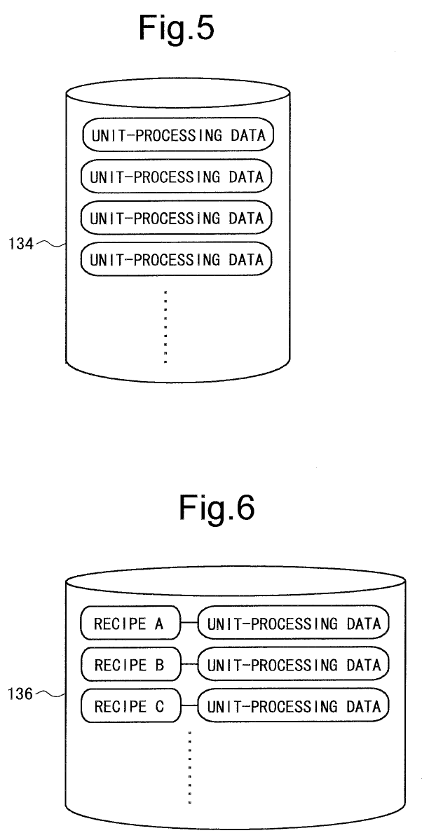

Next, the configuration of the controller 100 of the substrate processing apparatus 1 will be described. FIG. 4 is a block diagram showing a hardware configuration of the controller 100. The controller 100 includes a CPU 110, a main memory 120, an auxiliary storage device 130, a display 140, an input part 150, and a communication controller 160. The CPU 110 performs various arithmetic processing and the like in accordance with a given command. The main memory 120 temporarily stores programs under execution, data, and the like. The auxiliary storage device 130 stores various programs and various pieces of data to be held even when the power is turned off. In the present embodiment, specifically, a data processing program 132 for executing data processing, described later, is stored in the auxiliary storage device 130. Further, the auxiliary storage device 130 is provided with time series data DB 134 and a reference data DB 136. “DB” stands for “database.” As schematically shown in FIG. 5, unit-processing data for a predetermined period is stored in the time series data DB 134. As schematically shown in FIG. 6, the reference data DB 136 stores unit-processing data defined as reference data for each recipe (“recipe A”, “recipe B”, and “recipe C” represent different recipes). For example, the display 140 displays various screens for an operator to perform work. The input part 150 is, for example, a mouse, a keyboard, or the like, and accepts an input from the outside by the operator. The communication controller 160 controls data transmission and reception.

When the substrate processing apparatus 1 is activated, the data processing program 132 is read into the main memory 120, and the CPU 110 executes the data processing program 132 read into the main memory 120. As a result, the substrate processing apparatus 1 functions as a data processing apparatus. Note that the data processing program 132 is provided in the form of being recorded on a recording medium such as a CD-ROM, a DVD-ROM, a flash memory, or the like, or in the form of being downloaded via a network.

### 4. DATA PROCESSING METHOD CONCERNING THE CHANGE IN THE REFERENCE DATA

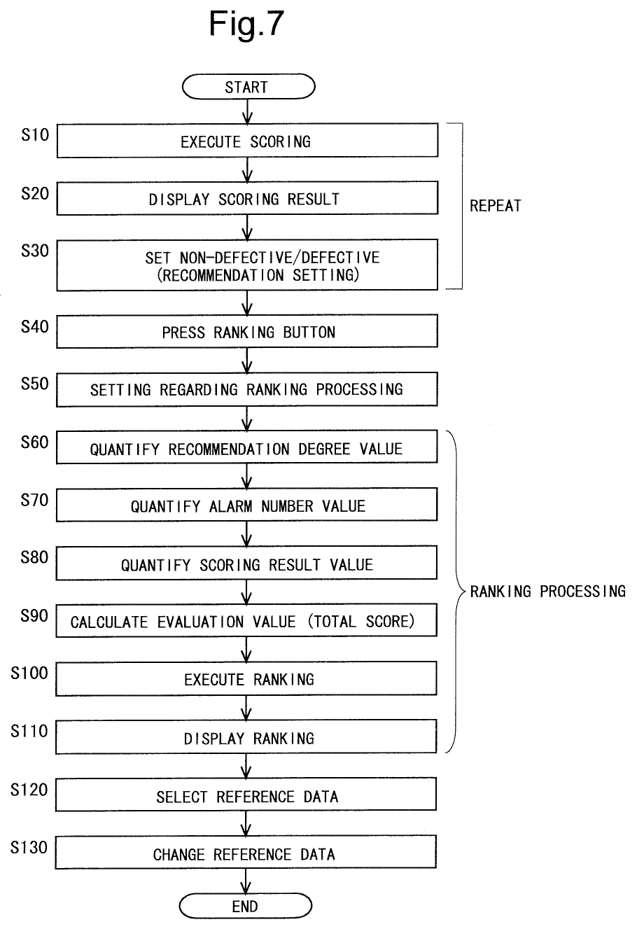

In the substrate processing apparatus 1 according to the present embodiment, it is possible to change the reference data for each recipe as needed. Hereinafter, focusing on one recipe, a description will be given of a procedure for changing the reference data. FIG. 7 is a flowchart showing the procedure for data processing concerning the change in the reference data. A series of processing shown in FIG. 7 is achieved by CPU 110 in the controller 100 executing the data processing program 132 in the substrate processing apparatus 1. Note that, in the following description, unit-processing data to be evaluated is referred to as “evaluation target data.”

First, a target recipe (hereinafter referred to as a “focused recipe”) is executed in the substrate processing apparatus 1, and scoring is performed based on the evaluation target data obtained from the processing unit 22 in which the focused recipe is executed (step S10). Note that the scoring is processing of making comparison in time series data of each parameter between the evaluation target data and the reference data, and digitizing the result obtained by the comparison. If the focused recipe is executed by the eight processing units 22, the scoring is performed based on each of the eight pieces of evaluation target data obtained from the eight processing units 22 (i.e., the scoring is performed for each unit-processing), so that eight scoring results are obtained. In the scoring, “non-defective” or “defective” is determined for a plurality of evaluation items. This determination is made, for each parameter, by comparing an inspection value, obtained based on the time series data included in the evaluation target data and the time series data included in the reference data, with a threshold corresponding to the inspection value (substantially, the determination is made by comparing the time series data included in the evaluation target data with the time series data included in the reference data). In this regard, when the inspection value exceeds the threshold, the corresponding evaluation item is determined to be “defective.” Note that a plurality of evaluation items may be provided for one parameter. In the present embodiment, the scoring result of each piece of evaluation target data is represented in a mode in which the denominator is taken as the total number of evaluation items and the numerator is taken as the number of evaluation items determined as defective.

Examples of evaluation items are listed below.

Example 1: An average value of time series data in a stable period (see FIG. 2) concerning a certain parameter

Example 2: The maximum value of time series data in the stable period (see FIG. 2) concerning a certain parameter

Example 3: A length of a rising period (see FIG. 2) concerning a certain parameter

Concerning the evaluation item of Example 1, “the difference between the average value of the time series data included in the evaluation target data and the average value of the time series data included in the reference data” in the stable period concerning the target parameter is the above inspection value. Concerning the evaluation item of Example 2, “the difference between the maximum value of the time series data included in the evaluation target data and the maximum value of the time series data included in the reference data” in the stable period concerning the target parameter is the above inspection value. Concerning the evaluation item of Example 3, “the difference between the length of the rising period for the time series data included in the evaluation target data and the length of the rising period for the time series data included in the reference data” is the above inspection value.

Meanwhile, at the time of the scoring, each time series data may be normalized. For example, with respect to each parameter, linear conversion may be performed on the time series data included in the evaluation target data so that the maximum value of the time series data included in the reference data is converted into 1 and the minimum value thereof is converted into 0. Although the time series data on each of a plurality of parameters is generally included in the evaluation target data, the time series data on each of only some parameters may be normalized. By normalizing the time series data as necessary, it is possible to more suitably calculate an evaluation value described later.

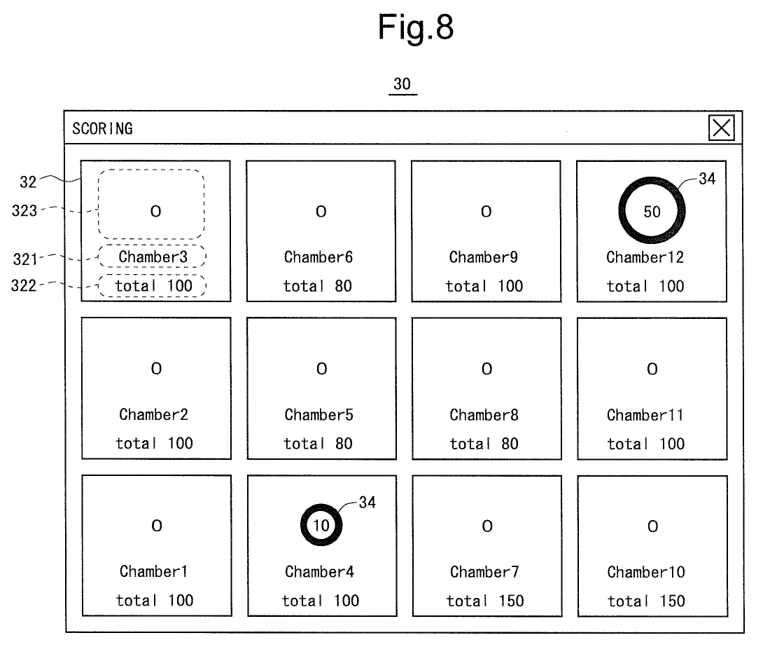

After the scoring is completed, the result of the scoring is displayed (step S20). In this regard, firstly, the scoring screen 30 showing the outline of the scoring result, for example as shown in FIG. 8, is displayed on the display 140. The scoring screen 30 is provided with buttons 32 in number equal to the number of processing units 22. In the button 32, a processing unit name display area 321, a processed number display area 322, and an error number display area 323 are provided. In the processing unit name display area 321, the name of the corresponding processing unit 22 is displayed. In the processed number display area 322, the total number of substrates processed within a predetermined period in the chamber in the corresponding processing unit 22 is displayed. In the error number display area 323, the number of generated error cases is displayed. For the processing unit 22 in which an error has occurred, a circle having a size corresponding to the number of error cases is displayed in the error number display area 323 as denoted by reference numeral 34.

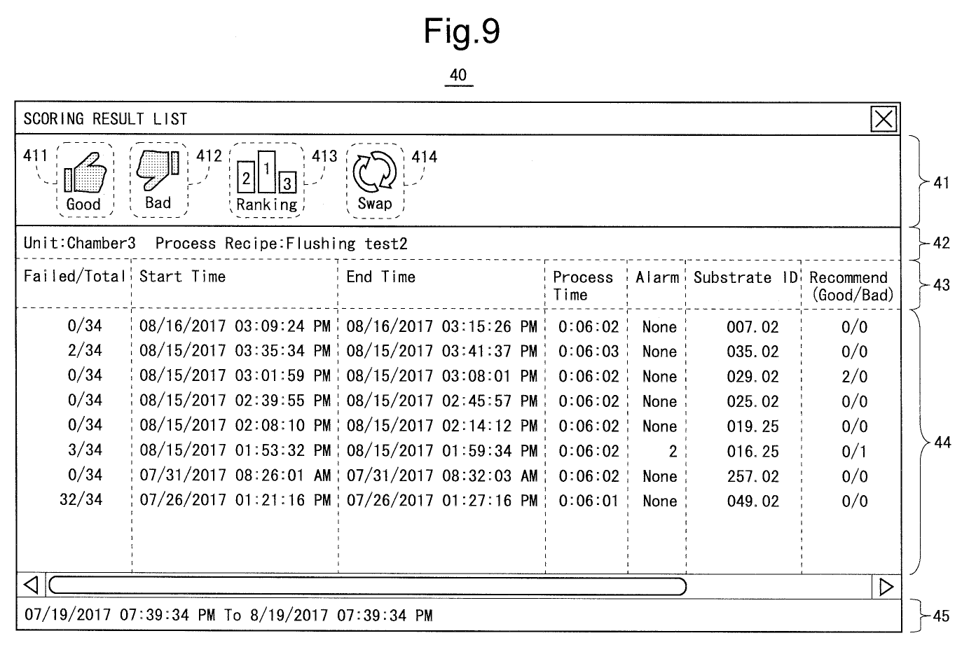

When any one of the buttons 32 on the scoring screen as described above is pressed, a screen showing the scoring result of the unit-processing executed by the corresponding processing unit 22 is displayed. Then, when one unit-processing is selected on the screen, a scoring result list screen 40, which displays a lift of scoring results for the recipe corresponding to the selected unit-processing, for example as shown in FIG. 9, is displayed on the display 140.

As shown in FIG. 9, the scoring result list screen 40 includes a button display area 41, a search target display area 42, an item name display area 43, a result display area 44, and a period display area 45. In the button display area 41, a Good button 411, a Bad button 412, a Ranking button 413, and a Swap button 414 are provided.

In the search target display area 42, the name of the processing unit 22 to be searched and the name of the recipe to be searched (in this case, the focused recipe) are displayed. In the example shown in FIG. 9, it is grasped that the name of the processing unit 22 to be searched is “Chamber3” and the name of the recipe to be searched is “Flushing test2.”

In the item name display area 43, the item name of the content (attribute data) to be displayed in the result display area 44 is displayed. “Failed/Total” is an item name representing the scoring result. Note that “Failed” corresponds to the number of evaluation items determined to be defective, and “Total” corresponds to the total number of evaluation items. “Start time” is an item name representing the start time of the focused recipe. “End time” is an item name representing the end time of the focused recipe. “Process time” is an item name representing the processing time of the focused recipe. “Alarm” is an item name representing the number of alarms generated at the time of executing the focused recipe. “Substrate ID” is an item name representing a number for uniquely identifying a substrate (wafer) on which processing based on the focused recipe has been performed. “Recommend (Good/Bad)” is an item name representing the recommendation degree described later. Note that “Good” corresponds to a value representing the degree of high evaluation (hereinafter referred to as “Good value”), and “Bad” corresponds to a value representing the degree of low evaluation (hereinafter referred to as “Bad value”). The recommendation degree is made up of these Good value and Bad value.

In the result display area 44, attribute data (various pieces of information, scoring results, etc.) of the unit-processing data matching a search condition is displayed. In the example shown in FIG. 9, attribute data of each of eight pieces of unit-processing data is displayed in the result display area 44. The operator can select one piece of attribute data (one row) from the pieces of attribute data displayed in the result display area 44.

In the period display area 45, a preset search target period is displayed. The attribute data of the unit-processing data obtained by executing the focused recipe in this search target period is displayed in the result display area 44. In the example shown in FIG. 9, it is grasped that the search target period is one month from 7:39:34 pm on Jul. 19, 2017 to 7:39:34 pm on Aug. 19, 2017.

A function of each button provided in the button display area 41 will be described here. The Good button 411 is a button for the operator to press when it is desired to raise the evaluation value of the unit-processing data corresponding to the attribute data selected in the result display area 44. The Bad button 412 is a button for the operator to press when it is desired to lower the evaluation value of the unit-processing data corresponding to the attribute data selected in the result display area 44. The Ranking button 413 is a button for instructing execution of ranking processing. The Swap button 414 is a button for defining the unit-processing data corresponding to the attribute data selected in the result display area 44 as new reference data. Note that the evaluation value and the ranking processing will be described later.

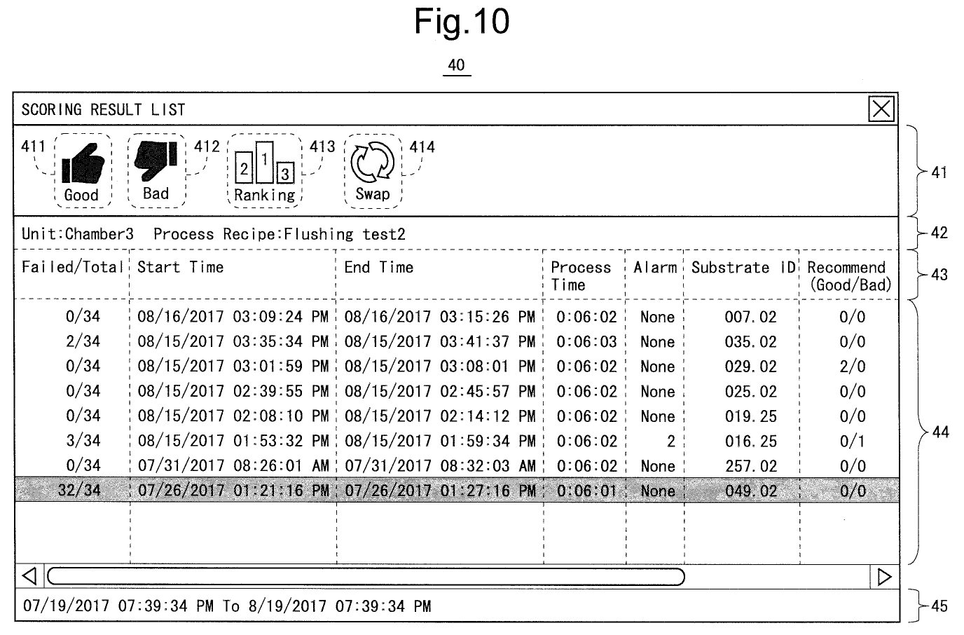

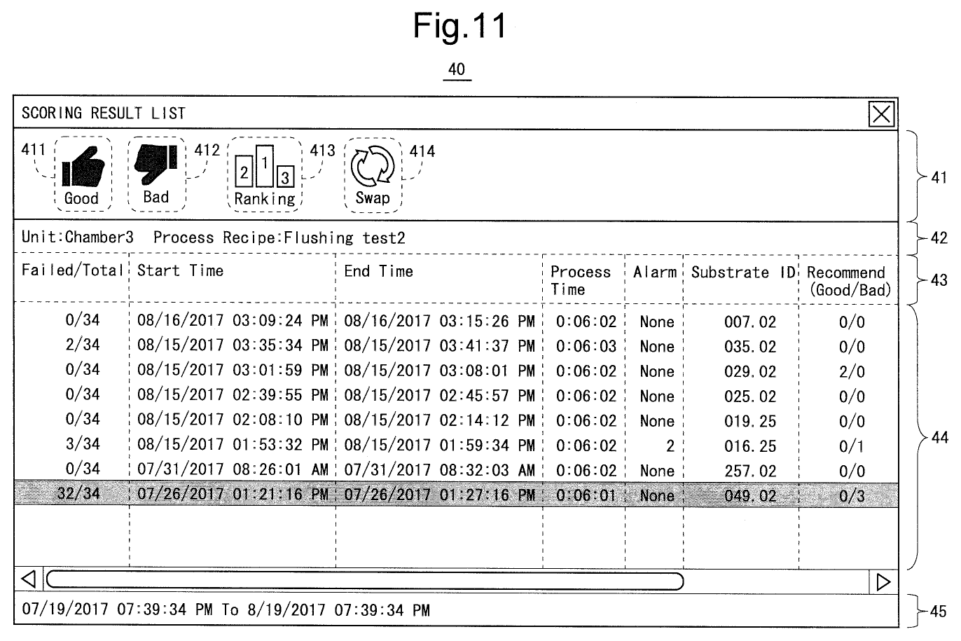

After displaying the scoring result list screen 40, setting (recommendation setting) of the recommendation degree representing the degree of recommending each piece of unit-processing data as reference data is performed as necessary (step S30). The recommendation setting is performed by pressing the Good button 411 or the Bad button 412 in a state where the attribute data corresponding to the unit-processing data to be set among the attribute data displayed in the result display area 44 is selected. At that time, the operator presses the Good button 411 when the unit-processing data to be set is preferable as the reference data, and the operator presses the Bad button 412 when the unit-processing data to be set is not preferable as the reference data. In this regard, immediately after the displaying of the scoring result list screen 40, the Good button 411 and the Bad button 412 are in an un-selectable state. When the operator selects any of the attribute data displayed in the result display area 44 in this state, the corresponding attribute data comes into a selected state and the Good button 411 and the Bad button 412 come into the selectable state as shown in FIG. 10. The operator presses the Good button 411 or the Bad button 412 in this state to add the Good value and the Bad value. For example, when the Bad button 412 is pressed three times from the state shown in FIG. 10, the Bad value of the selected attribute data is “3” as shown in FIG. 11. As described above, the scoring result list screen 40 is configured such that the recommendation degree can be changed from the outside. Note that specifically what value is to be set for the Good value or the Bad value is determined considering, for example, the scoring result, the number of alarms, the state of the resultant object (substrate) obtained in the corresponding unit-processing (e.g., the number of particles, the number of defects, a collapse rate), and the like. In addition to the Good button 411 and the Bad button 412, a button for reducing the Good value and a button for reducing the Bad value may be provided.

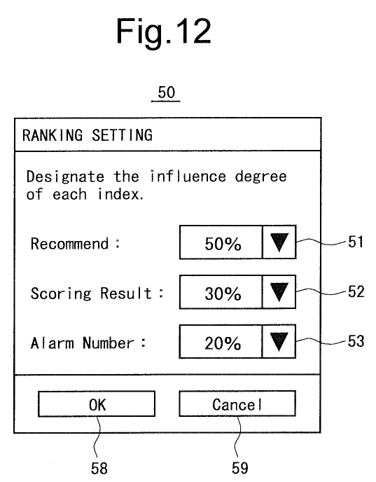

Meanwhile, each recipe is normally executed a plurality of times from the change in the reference data at a certain point of time until the next change in the reference data. That is, the scoring is usually executed a plurality of times from the change in the reference data at a certain point of time until the next change in the reference data. Therefore, with respect to a series of processing (a series of processing shown in FIG. 7) for changing the reference data once, the processing of step S10 to step S30 is usually repeated a plurality of times. When it is desired to change the reference data, the operator presses the Ranking button 413 in the scoring result list screen 40 (step S40). As a result, a ranking setting screen 50, for example as shown in FIG. 12, is displayed on the display 140. The ranking setting screen is a screen for setting regarding ranking processing described later.

The ranking processing will be described here. The ranking processing in the present embodiment is a series of processing to perform, based on three indices, ranking on a plurality of pieces of unit-processing data (unit-processing data in a search target period) obtained by executing a designated recipe, and displaying the result of the ranking in a ranking format. Note that the ranking format refers to a format in which data is ranked in order from data ranked high to data ranked low. The rank of each piece of unit-processing data is determined by an evaluation value (total score) calculated based on the three indices. In the present embodiment, as the three index values for calculating the evaluation value, there are used a value based on the above-mentioned recommendation degree (hereinafter referred to as “recommended value”), a value based on the scoring result (hereinafter referred to as “scoring result value”), and a value based on the number of occurrence of alarms (or presence or absence of an alarm) (hereinafter referred to as “alarm value”). A specific way to obtain the evaluation value will be described later. In the ranking processing, a plurality of pieces of unit-processing data within the search target period are ranked based on the evaluation value, and attribute data corresponding to each piece of unit-processing data is displayed in the ranking format.

In step S50, a setting necessary for executing the ranking processing as described above is performed by the operator's operation using the ranking setting screen 50. FIG. 12 is a view showing an example of the ranking setting screen 50. As shown in FIG. 12, this ranking setting screen 50 includes an OK button 58, a cancel button 59, and three drop-down lists 51 to 53 for setting the influence degree (degree of contribution) of each of the above three index values at the time of calculating the evaluation value for determining the rank of each piece of unit-processing data. The drop-down list 51 is an interface for setting the influence degree of the recommended value. The drop-down list 52 is an interface for setting the influence degree of the scoring result value. The drop-down list 53 is an interface for setting the influence degree of the alarm value. The OK button 58 is a button for executing the ranking processing (the processing of steps S60 to S110) based on the setting contents. The Cancel button 59 is a button for canceling the setting contents (the contents having been set using the drop-down lists 51 to 53) and returning to the scoring result list screen 40.

For the drop-down lists 51 to 53, it is possible to set the influence degree at a step of 1%, for example. However, it is also possible to set the influence degree at a step of 5% or 10%. For the one that is not to be used as an index value at the time of calculating the evaluation value, it is possible to set the influence degree to 0%.

Meanwhile, when the setting value in the drop-down list 51 is defined as a “first setting value”, the setting value in the drop-down list 52 is defined as a “second setting value”, and the setting value in the drop-down list 53 is defined as a “third setting value”, it is preferable to automatically adjust the values such that the sum of the first setting value, the second setting value, and the third setting value becomes 100%. In this regard, the configuration may be such that, when values are set for two drop-down lists after the displaying of the ranking setting screen 50, the value of the remaining drop-down list is set automatically. In this case, for example, when the setting of “first set value=50, second set value=30” is made, the third set value is automatically set to “20.” Alternatively, the configuration may be such that, when the value for any one drop-down list is changed in a state where values for the three drop-down lists have already been set, the values for the remaining two drop-down lists are automatically changed while maintain the ratio thereof. In this case, for example, when the first setting value is changed to “55” in a state where “first setting value=70, second setting value=20, and third setting value=10” has been set, the second setting value is automatically changed to “30”, and the third setting value is automatically changed to “15.”

Note that, the configuration may be such that, such setting that the sum of the first set value, the second set value and the third set value exceeds 100% is accepted and internal processing is performed so as to make the sum be 100% while maintaining the ratio. Further, the configuration may be such that, when such setting that the sum of the first set value, the second set value and the third set value exceeds 100% is performed, a message indicating “the sum exceeds 100%” is displayed to prompt resetting.

After the influence degrees of the three index values have been set, when the OK button 58 on the ranking setting screen 50 is pressed, the ranking processing (processing of steps S60 to S110) is started. In the ranking processing, all pieces of unit-processing data, obtained from each processing unit 22 by the focused recipe being executed in the search target period, become evaluation target data.

First, the above recommended value is obtained for each piece of evaluation target data which can be candidates for reference data (step S60). When the Good value is represented as CntG and the Bad value is represented as CntB, a recommended value V(R) is calculated by the following Formula (1), for example.

V(R)=(CntG−CntB)×100/(CntG+CntB) (1)

Here, when “CntG=0” and “CntB=0”, “V(R)=0” is set.

Next, the above alarm value is obtained for each piece of evaluation target data (step S70). For the alarm value V(A), for example, “V(A)=100” is set when the number of alarms is 0 (indicated as “None” on the scoring result list screen 40), and “V(A)=−100” is set when the number of alarms is 1 or more.

Next, the above scoring result value V(S) is obtained for each piece of evaluation target data (step S80). When the total number of evaluation items is represented as Nt and the number of evaluation items determined as defective is represented as Nf, the scoring result value V(S) is calculated by the following Formula (2), for example.

V(S)(Nt−2×Nf)×100/Nt (2)

After the recommended value V(R), the alarm value V(A), and the scoring result value V(S) have been obtained as described above, the above evaluation value (total score) is calculated for each piece of evaluation target data (step S90). When the values (proportions) of the drop-down lists 51 to 53 set in step S50 are respectively represented as P1 to P3, the evaluation value (total score) Vtotal is calculated by the following Formula (3).

Vtotal=V(R)×P1+V(S)×P2+V(A)×P3 (3)

After the calculation of the evaluation values for all pieces of unit-processing data (evaluation target data) that can be candidates for the reference data, ranking on the unit-processing data is performed based on the calculated evaluation value (step S100). At that time, unit-processing data with a larger evaluation value is ranked higher (a numerical value representing the rank becomes smaller). Therefore, the unit-processing data ranked as the first is the unit-processing data having the largest evaluation value.

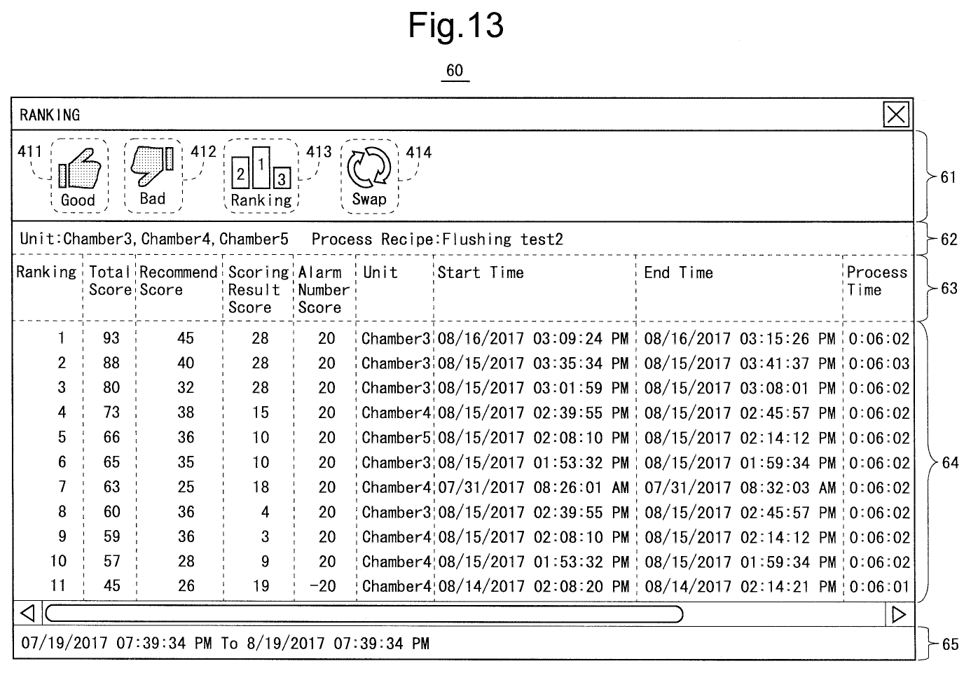

After completion of the ranking, a ranking screen 60 representing the result of the ranking, for example as shown in FIG. 13, is displayed on the display 140 (step S110). As shown in FIG. 13, attribute data for a plurality of pieces of unit-processing data is displayed on the ranking screen 60 in the ranking format in accordance with the ranking results.

The ranking screen 60 includes a button display area 61, a search target display area 62, an item name display area 63, a result display area 64, and a period display area 65. Like the scoring result list screen 40, a Good button 411, a Bad button 412, a Ranking button 413, and a Swap button 414 are provided in the button display area 61.

In the search target display area 62, the name of the processing unit 22 to be searched and the name of the recipe to be searched (in this case, the focused recipe) are displayed. In the example shown in FIG. 13, it is grasped that the names of the processing units 22 to be searched are “Chamber3”, “Chamber4”, and “Chamber5” and the name of the recipe to be searched is “Flushing test2.” While only the processing unit 22 selected on the scoring screen 30 (see FIG. 8) has been the search target on the scoring result list screen 40 (see FIG. 9), all the processing units 22 for which the focused recipe is executed in the search target period are search targets on the ranking screen 60.

In the item name display area 63, the item name of the content (attribute data) to be displayed in the result display area 64 is displayed. “Ranking” is an item name representing a rank based on the ranking. “Total Score” is an item name representing the evaluation value (total score). “Recommend Score” is an item name representing a value (V(R)×P1) obtained by multiplying the recommended value by the ratio set in the drop-down list 51 of the ranking setting screen 50. “Scoring Result Score” is an item name representing a value (V(S)×P2) obtained by multiplying the scoring result value by the ratio set in the drop-down list 52 of the ranking setting screen 50. “Alarm Number Score” is an item name representing a value (V(A)×P3) obtained by multiplying the alarm value by the ratio set in the drop-down list 53 of the ranking setting screen 50. “Unit” is an item name representing the processing unit. “Start time” is an item name representing the start time of the focused recipe. “End time” is an item name representing the end time of the focused recipe. “Process time” is an item name representing the processing time of the focused recipe.

In the result display area 64, attribute data (various pieces of information, ranks based on ranking, etc.) of the unit-processing data matching a search condition is displayed. As can be grasped from FIG. 13, in the result display area 64, the attribute data of the unit-processing data is displayed in a state sorted from one having a high evaluation value to one having a low evaluation value. Therefore, the unit-processing data corresponding to attribute data displayed on the first row of the result display area 64 is the unit-processing data having the largest evaluation value among the unit-processing data matching the search condition. The operator can select one piece of attribute data (one row) from the pieces of attribute data displayed in the result display area 64.

As in the period display area 45 of the scoring result list screen 40, the search target period is displayed in the period display area 65. In the example shown in FIG. 13, it is grasped that the search target period is one month from 7:39:34 pm on Jul. 19, 2017 to 7:39:34 pm on Aug. 19, 2017.

After displaying of the ranking screen 60, the reference data after change is selected by the operator (step S120). Specifically, the operator selects attribute data corresponding to unit-processing data to be set as the reference data after change from the attribute data displayed in the result display area 64 on the ranking screen 60. This brings the selected attribute data into the selected state on the ranking screen 60. In this state, the operator presses the Swap button 414 in the button display area 61. As a result, the reference data for the focused recipe is changed (step S130). Specifically, the unit-processing data corresponding to the focused recipe among the unit-processing data held in the reference data DB 136 (see FIG. 6) is rewritten to unit-processing data corresponding to the attribute data in the selected state in the result display area 64. Since the reference data can be determined based on the ranking result as described above, it is possible to define the unit-processing data having an ideal time series value as the reference data after change.

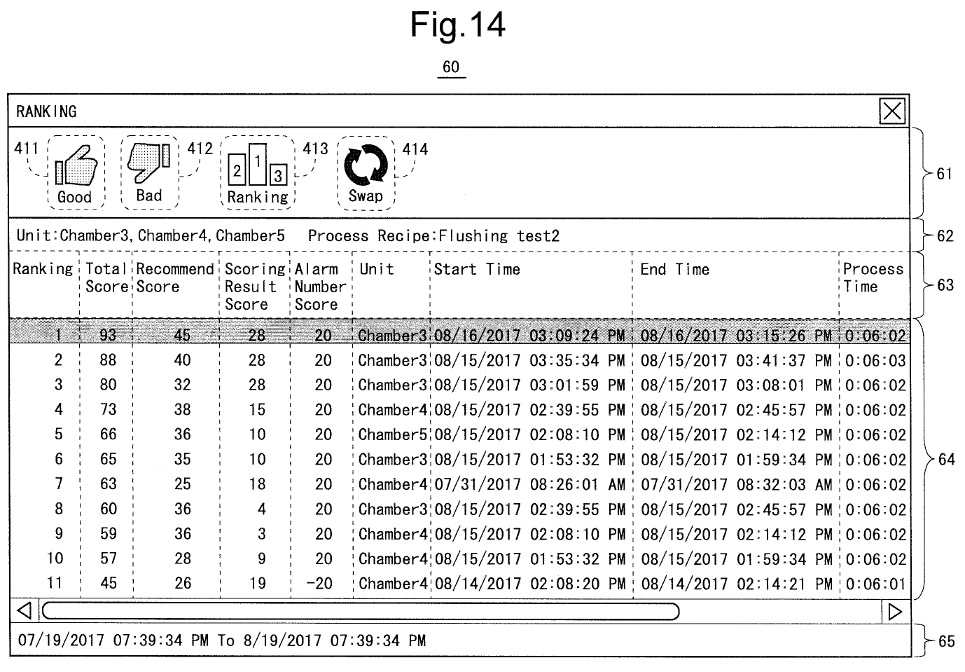

For example, when the operator selects the attribute data on the first row in the result display area 64 while the ranking screen 60 is in the state shown in FIG. 13, the attribute data on the first row comes into the selected state and the Swap button 414 comes into a pressable state as shown in FIG. 14. When the operator presses the Swap button 414 in this state, the reference data for the focused recipe is changed to the unit-processing data corresponding to the attribute data on the first row.

Note that, according to the present embodiment, it is also possible to select unit-processing data with a rank other than the first rank based on the ranking as the reference data. In this manner, it is possible to select the reference data matching the needs of the user.

By changing the reference data as described above, the series of processing shown in FIG. 7 is completed. Note that, in the present embodiment, a unit-processing data evaluating step is achieved by the steps S10 to S90, and a reference data changing step is achieved by the steps S100 to S130. Further, a data comparing step is achieved by the step S10, a comparison result displaying step is achieved by the step S20, a contribution degree setting step is achieved by the step S50, a recommendation degree scoring step is achieved by the step S60, an alarm frequency scoring step is achieved by the step S70, a comparison result soring step is achieved by the step S80, an evaluation value calculating step is achieved by the step S90, a ranking displaying step is achieved by the step S110, and a reference data selecting step is achieved by the step S120.

### 5. METHOD FOR DETERMINING FIRST REFERENCE DATA

In the above description, it has been assumed that the reference data has already been determined (i.e., unit-processing data as the reference data has been held in the reference data DB 136). However, there is no reference data at the time when the use of the substrate processing apparatus 1 is started after the manufacturing of the substrate processing apparatus 1 has been completed. It is thus necessary to determine first reference data by some method. Therefore, a specific example concerning a method for determining the first reference data will be described.

### 5.1 First Example

Generally, when the manufacturing of the substrate processing apparatus is completed, various tests are performed regarding the substrate processing apparatus. Only after passage of these tests, the actual use of the substrate processing apparatus is started. Thus, unit-processing data which is obtained when the recipe is first executed in a certain processing unit 22 after the passage of the tests can be defined as the first reference data for the recipe.

For example, in a case in which twelve processing units 22 are provided in the substrate processing apparatus 1, when the same recipe is executed in the twelve processing units 22, twelve pieces of unit-processing data are obtained. With respect to such a case, when a configuration in which the reference data is defined for each processing unit 22 for each recipe is adopted, it is possible to define each of the twelve pieces of unit-processing data as reference data for the corresponding processing unit 22.

### 5.2 Second Example

During a predetermined period after the start of actual use of the substrate processing apparatus 1, the operation is performed without making definition of the reference data. Meanwhile, after execution of the recipe in the substrate processing apparatus 1, for each substrate (wafer) on which processing has been performed, a predetermined inspection is performed for determining whether the processing result is good or bad (the obtained result is good or bad). As a result, information such as the number of particles, the number of defects, and a collapse rate can be obtained for each substrate. Thus, it is possible to define the unit-processing data at the time of processing the substrate from which the best processing result has been obtained as the first reference data for the target recipe, based on these pieces of information obtained during the above predetermined period.

### 5.3 Third Example

During a predetermined period after the start of actual use of the substrate processing apparatus 1, the operation is performed without making definition of the reference data. Meanwhile, when the recipe is executed in the substrate processing apparatus 1, information on the number of alarms is obtained for each unit-processing. Note that the number of alarms is the number of items corresponding to a predetermined error condition, which is obtained without requiring processing to compare the unit-processing data with the reference data. Thus, it is possible to define the unit-processing data obtained by unit-processing with the smallest number of alarms (when there are plural, any thereof) as the first reference data for the target recipe, based on the information on the number of alarms obtained during the above predetermined period.

### 5.4 Fourth Example

When a certain substrate processing apparatus 1 is manufactured, a substrate processing apparatus 1 of the same type as the certain substrate processing apparatus 1 may have already been used. In such a case, it is possible to define the unit-processing data, defined as the reference data in the substrate processing apparatus 1 having already been used, as the first reference data in the substrate processing apparatus 1 immediately after manufacturing.

### 6. EFFECTS

According to the present embodiment, in the substrate processing apparatus 1, an evaluation value is calculated for each piece of unit-processing data which is a group of pieces of time series data obtained by the unit-processing. At that time, the evaluation value is calculated by comparing the unit-processing data to be evaluated with the reference data previously defined. Therefore, the magnitude of the degree of similarity between the unit-processing data to be evaluated and the reference data can be reflected to the evaluation value of the unit-processing data to be evaluated. Then, since the reference data is changed based on the evaluation value, unit-processing data having a high degree of similarity to the reference data before change can be defined as the reference data after change. Since the reference data is preferably defined in this way, by comparing the time series data included in each piece of unit-processing data with the time series data included in the reference data, it is possible to accurately detect an abnormality in the processing executed in the substrate processing apparatus 1. As described above, according to the present embodiment, it is possible to perform the abnormality detection using time series data more accurately than before.

### 7. MODIFIED EXAMPLES

Modified examples of the above embodiment will be described below.

### 7.1 First Modified Example

In the above embodiment, at the time of changing the reference data, the unit-processing data to be set as the reference data after change is selected by the operator on the ranking screen 60. However, the present invention is not limited thereto. The reference data may be automatically changed in accordance with the ranking result, without requiring the operator's operation. (the operation to select the reference data).

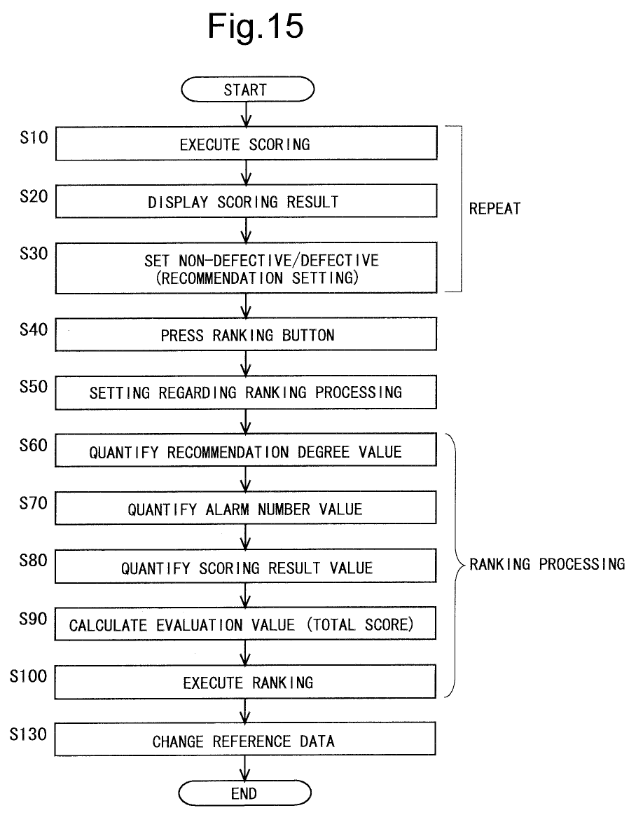

FIG. 15 is a flowchart showing a procedure of data processing concerning the change in the reference data in the present modified example. As in the above embodiment, also in the present modified example, after the calculation of the evaluation value for all pieces of unit-processing data (evaluation target data) that can be candidates for the reference data, ranking on the unit-processing data is performed based on the calculated evaluation value (step S100). By this step S100, the unit-processing data having the largest evaluation value is set to be ranked as the first. Then, unlike the above embodiment, without displaying the ranking screen 60 on the display 140, reference data for the focused recipe is changed to the unit-processing data ranked as the first (step S130). As a result, unit-processing data having an ideal time series value is reliably defined as the reference data. According to the present modified example, it is impossible to set the unit-processing data ranked as the second or lower as the reference data, but the operation load of the operator is reduced. In addition, inappropriate unit-processing data is prevented from being set as the reference data due to an error in the operator's operation.

### 7.2 Second Modified Example

In the above embodiment, setting regarding the ranking processing (step S50 in FIG. 7) is performed immediately before execution of the ranking processing. However, the present invention is not limited thereto. Setting regarding the ranking processing may be performed before performance of the scoring.

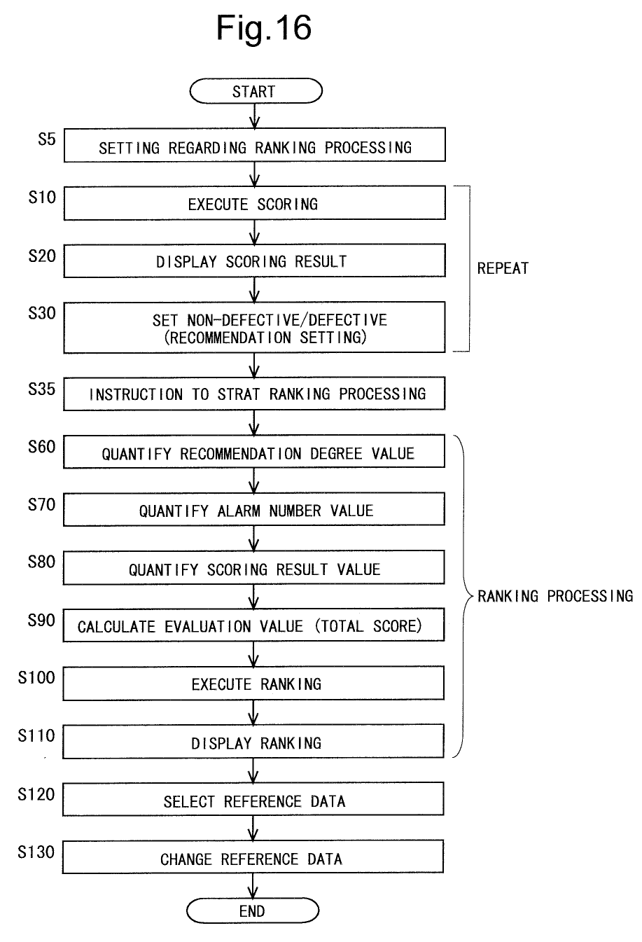

FIG. 16 is a flowchart showing a procedure of data processing concerning the change in the reference data in the present modified example. In the present modified example, a menu for commanding the start of the setting regarding the ranking processing is provided on a predetermined screen displayed on the display 140 after the start of execution of the data processing program 132. Then, when the menu is selected, the ranking setting screen 50 as shown in FIG. 12 is displayed on the display 140, and the setting regarding the ranking processing (specifically, the setting of the influence degree for each of the three index values) is performed in the same manner as in the above embodiment (step S5). Note that, in the present modified example, when the OK button 58 on the ranking setting screen 50 is pressed, the screen returns to the predetermined screen.

Thereafter, the scoring (step S10), the display of the scoring result (step S20), and the recommendation setting (step S30) are performed each time the target recipe (the focused recipe) is executed. However, the recommendation setting is performed only when necessary.

Thereafter, the operator selects a “menu for commanding the start of the ranking processing”, for example, provided in the predetermined screen, or a “command for commanding the start of the ranking processing” is issued in accordance with a previously set rule or the like, so that the ranking processing is started (step S35). Then, the ranking processing is performed in the same manner as in the above embodiment, and the reference data is changed based on the result of the ranking processing (steps S60 to S130). Note that the configuration may be such that the reference data for the focused recipe is changed to the unit-processing data ranked as the first by the ranking processing without displaying the ranking screen 60 in the same manner as in the first modified example.

### 7.3 Third Modified Example

In the above embodiment, three index values (recommended value, scoring result value, alarm value) are prepared as the index values for calculating the evaluation value of the unit-processing data. However, the present invention is not limited thereto. Two or less index values or four or more index values may be prepared. In this regard, index values other than the index values described in the above embodiment may be prepared.

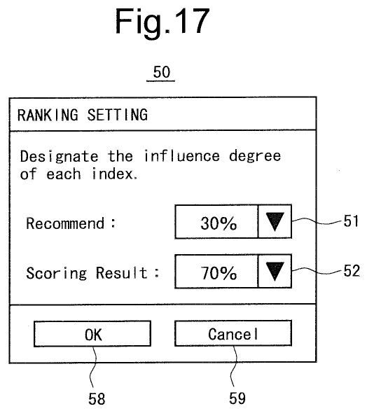

In the present modified example, the content displayed on the ranking setting screen 50 described above corresponds to the prepared index values. For example, in a case in which two index values (recommended value and scoring result value) are prepared as the index values, the ranking setting screen 50 is as shown in FIG. 17.

### 7.4 Fourth Modified Example

As related to the third modified example, the configuration may be such that an item which can be freely used by the user of the substrate processing apparatus 1 (hereinafter referred to as “free input item”) is provided in advance as an item of attribute data of the unit-processing data, and a value inputted into a free input item field is used as an index value for calculating the evaluation value. Data inputted into this free input item field corresponds to freely-inputted data. Specific examples of a value that may be inputted into the free input item field include the number of particles, the number of defects, and a collapse rate. Note that, in the following description, a case where two free input items are prepared in advance will be described.

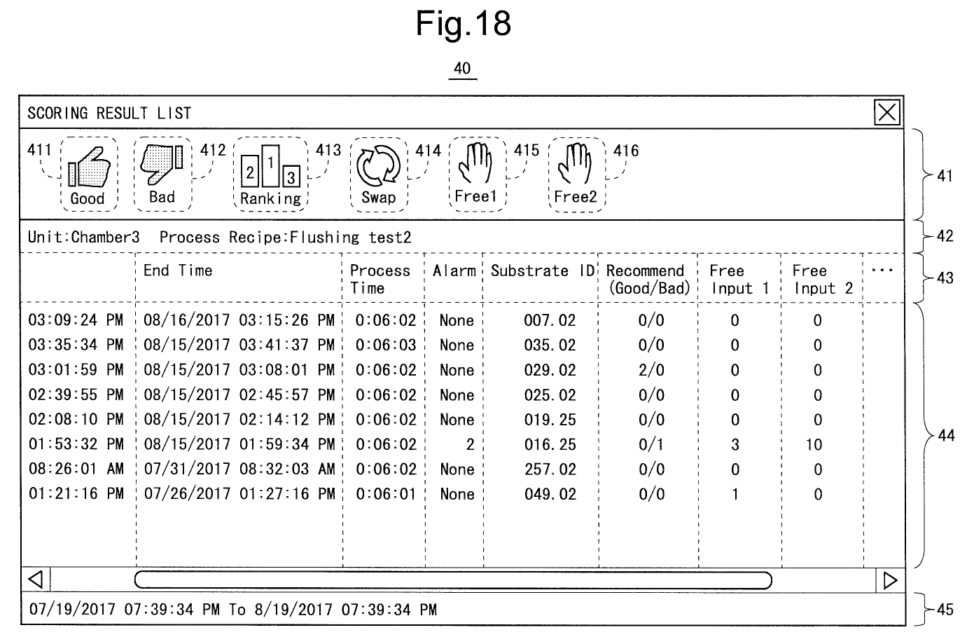

In the present modified example, as shown in FIG. 18, in the result display area 44 of the scoring result list screen 40, there are provided two free input item fields for each piece of unit-processing data. In the example shown in FIG. 18, item names of these fields are “Free Input 1” and “Free Input 2”. The item name may be changed by the operator. For convenience, the input value in the field with the item name “Free Input 1” is referred to as a “first free item value”, and the input value in the field with item name “Free Input 2” is referred to as a “second free item value.” In the button display area 41, in addition to the buttons provided in the above embodiment, a Free1 button 415 and a Free2 button 416 are provided. The Free1 button 415 is a button for inputting the first free item value, and the Free2 button 416 is a button for inputting the second free item value.

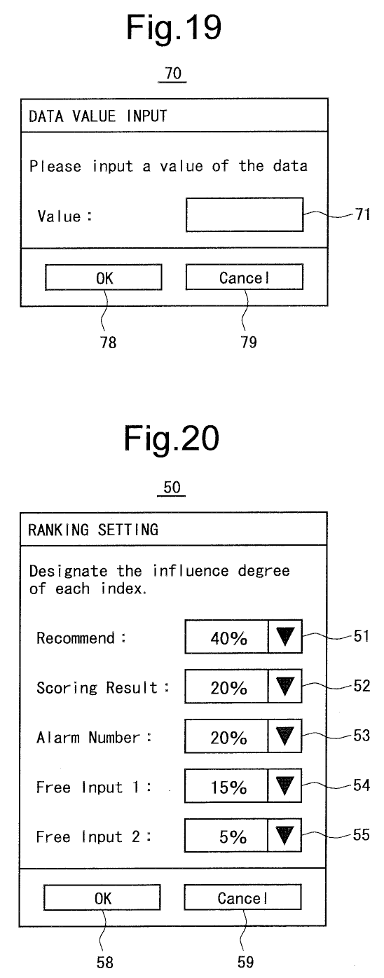

Immediately after displaying of the scoring result list screen 40, the Free1 button 415 and the Free2 button 416 are in an un-selectable state. When the operator selects any of the attribute data displayed in the result display area 44 in this state, the target attribute data comes into a selected state and the Free1 button 415 and the Free2 button 416 come into the selectable state. When the operator presses the Free1 button 415 or the Free2 button 416 in this state, a data value input screen 70, for example as shown in FIG. 19, is displayed on the display 140.

As shown in FIG. 19, the data value input screen 70 includes a text box 71 for inputting a first free item value or a second free item value, an OK button 78, and a Cancel button 79. The operator inputs a data value of the target item in a text box 71. Thereafter, when the OK button 78 is pressed, the content (data value) inputted into the text box 71 is reflected in the corresponding field in the result display area 44 of the scoring result list screen 40. On the other hand, when the Cancel button 79 is pressed, the content inputted into the text box 71 is canceled and the screen returns to the scoring result list screen 40. As described above, the scoring result list screen 40 in the present modified example is configured so that the value of the free input item field can be changed from the outside.

Note that, it is preferable that the input of the first free item value and the second free item value is performed, for example, immediately before or immediately after the recommendation setting (step S30 in FIG. 7) described above. In addition, the configuration may be such that, when a value to be inputted into a free input item field exists as electronic data, it is possible to capture the electronic data via a recording medium or a network. Thereby, the operation load for the input by the operator is reduced.

In the present modified example, when the Ranking button 413 on the scoring result list screen 40 is pressed, the ranking setting screen 50 as shown in FIG. 20 is displayed on the display 140. On this ranking setting screen 50, in addition to the drop-down lists 51 to 53 provided in the above embodiment, a drop-down list 54 for setting the influence degree of the first free item value and a drop-down list 55 for setting the influence degree of the second free item value are provided. In this manner, it is possible to set the influence degree of each of the five index values.

According to the present modified example, it is possible to add an index value for calculating the evaluation value as required. Hence it is possible to calculate the evaluation value in consideration of information that cannot be obtained from time series data. As a result, the unit-processing data to be used as the reference data is determined more preferably.

Note that, although the case where free input items are prepared in advance has been described in the above, the configuration may be such that a free input item field is added into the result display area 44 only after a predetermined menu is selected on the scoring result list screen 40, for example. In this case, for example, it is preferable that, in conjunction with the addition of the free input item field into the result display area 44, a drop-down list for setting the degree influence of the free input item is added to the ranking setting screen 50.

### 7.5 Fifth Modified Example

In the above embodiment, the scoring result of each evaluation target data is expressed in the mode in which the denominator is taken as the total number of evaluation items and the numerator is taken as the number of evaluation items determined as defective. Then, the scoring result value is obtained from such a scoring result. However, the present invention is not limited thereto. The configuration may be such that the time series data included in the evaluation target data and the time series data included in the reference data are compared directly without processing the data value and a scoring result value is obtained from the comparison result. This will be described below.

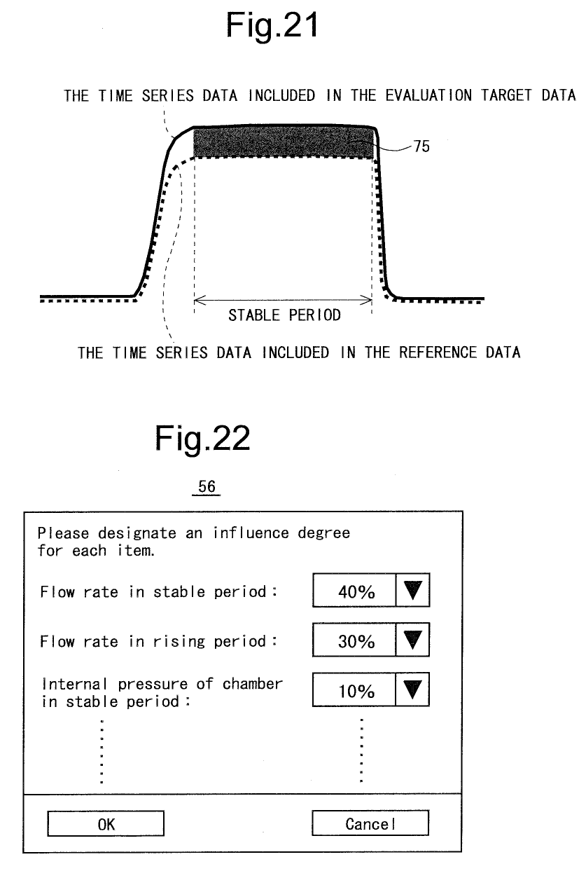

For example, focusing on a certain parameter, it is possible to obtain an integral value (a value representing an area of a hatched portion marked with reference numeral 75 in FIG. 21) of the difference between the value of the time series data included in the evaluation target data and the value of the time series data included in the reference data in a stable period. Considering that the scoring is performed based on a plurality of evaluation items, values such as the above integral value (hereinafter referred to as “direct comparison value” for convenience) can be obtained for each of the plurality of evaluation items. Meanwhile since the unit of the direct comparison value differs depending on the evaluation item, when the sum of direct comparison values of a plurality of evaluation items is simply defined as the scoring result value, the scoring result value is not a meaningful value. Therefore, in the same manner as the setting of the influence degree of each index value at the time of obtaining the evaluation value, for example, a screen, for example as shown in FIG. 22, may be displayed on the display 140 so that it is possible for the operator to set the influence degree of each evaluation item concerning the calculation of the scoring result value. This makes it possible to suitably obtain the scoring result value from the direct comparison value for a plurality of evaluation items.

Note that, the configuration may be such that, the evaluation value is obtained from the result of direct comparison between the time series data included in the evaluation target data and the time series data included in the reference data without processing the data value, while the recommended value or the alarm value is not considered at the time of calculating the evaluation value.

### 7.6 Sixth Modified Example

According to the above embodiment, the reference data which is the unit-processing data for comparison with the unit-processing data to be evaluated is changed as needed. In this regard, although only the latest reference data for each recipe is held in the reference data DB 136 in the above embodiment, past reference data may also be stored in the reference data DB 136. Further, the past reference data can also be stored in a database other than the reference data DB 136. In this manner, the history of the reference data may be left.

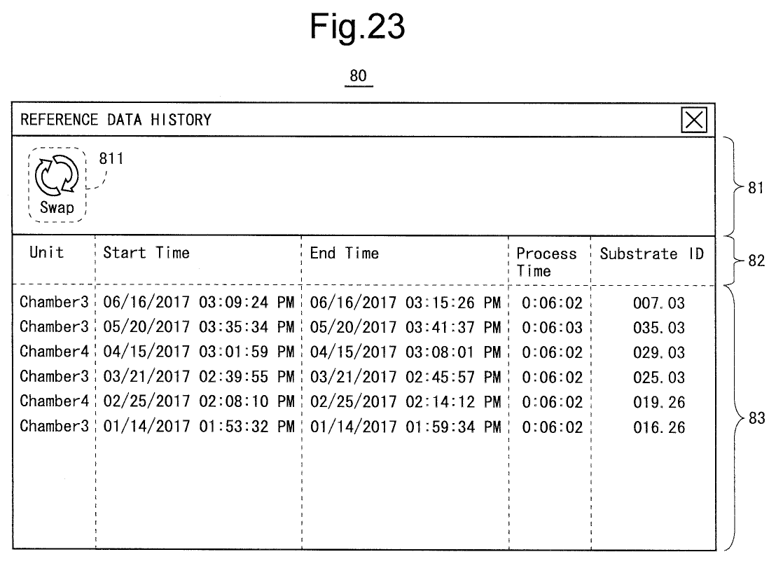

Thus, a function of restoring the past reference data as the current reference data using the history of the reference data may be provided. For example, the configuration may be such that a menu for displaying the history of the reference data is prepared in advance and when the menu is selected to specify a recipe, the reference data history screen 80 as shown in FIG. 23 is displayed on the display 140. As shown in FIG. 23, the reference data history screen 80 includes a button display area 81, an item name display area 82, and a history display area 83. In the button display area 81, a Swap button 811 is provided. In the item name display area 82, the item name of the content (attribute data) to be displayed in the history display area 83 (e.g., the item name representing the start time of the specified recipe) is displayed. In the history display area 83, attribute data of past reference data (unit-processing data defined as reference data in the past) for the specified recipe is displayed. In the example shown in FIG. 23, attribute data of the six pieces of past reference data are displayed in the history display area 83. The operator can select one piece of attribute data (one row) from the attribute data displayed in the history display area 83. The Swap button 811 is a button for restoring past reference data (unit-processing data determined in the past as reference data) corresponding to the attribute data selected in the history display area 83 as current reference data.

Immediately after displaying of the reference data history screen 80, the Swap button 811 is in an un-selectable state. When an operator selects one piece of attribute data displayed in the history display area 83 in this state, the target attribute data comes into a selected state and the Swap button 811 comes into a selectable state. When the operator presses the Swap button 811 in this state, regardless of the setting content on the change timing setting screen 70, the reference data is changed to the unit-processing data corresponding to the attribute data selected in the history display area 83. That is, the past reference data corresponding to the attribute data in the selected state in the history display area 83 is restored as the current reference data for the specified recipe.

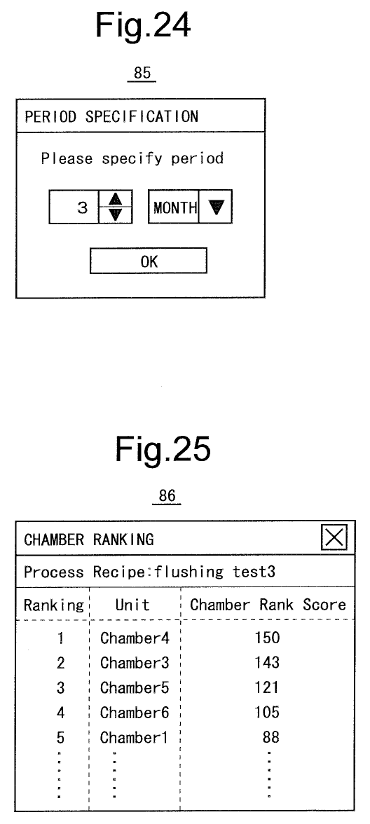

Note that, in connection with the present modified example, the configuration may be such that, a period specification screen 85 as shown in FIG. 24 is displayed on the display 140 to accept specification of a period by the operator, for example, after the recipe has been specified, and the history of the reference data in the case of assuming that the reference data has been changed for each specified period is displayed on the display 140. Thereby, for example, the history of the reference data assuming that the reference data is changed every seven days, the history of the reference data assuming that the reference data is changed every month, the history of the reference data assuming that the reference data is changed every year, and the like are displayed sequentially, and the results of those can be used for analysis of time series data.

### 7.7 Seventh Modified Example

In the above embodiment, ranking on a plurality of pieces of unit-processing data, obtained by executing a specified recipe within the search target period, is performed by the ranking processing. In this regard, ranking among aggregates as described below may be able to be performed in advance so that the population of the unit-processing data to be targets for a ranking processing can be specified.

For example, in a substrate processing apparatus, processing performance varies among a plurality of chambers. Therefore, the following function may be provided: “after accepting specification of a target recipe, the evaluation value is obtained in accordance with predetermined rules using all the unit-processing data obtained at the time when the target recipe is executed for each processing unit 22 (since the processing unit 22 and the chamber correspond one to one), and ranking on the processing units 22 is performed based on the evaluation value”. In this case, as a result of ranking, a chamber ranking screen 86, for example, as shown in FIG. 25 may be displayed on the display 140. By performing such ranking for the processing unit 22 for a large number of recipes, for example, it is possible to grasp a chamber (processing unit 22) that can obtain a favorable result whichever recipe is executed. Then, it is possible to accept selection of one or a plurality of processing units 22 prior to execution of the ranking processing (step S60 to step S110 in FIG. 7) and take only unit-processing data, obtained by the selected processing unit 22, as targets for the ranking processing.

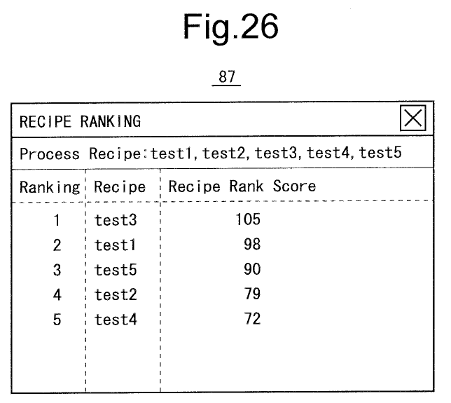

Further, for example, when attention is focused on a certain processing (e.g., SPM processing), the processing may be executed while the setting value of the parameter is changed little by little. In such a case, there is a plurality of recipes for this processing. In view of this, for example, in a case in which the reference data is determined for each processing, which is a concept involving a plurality of related recipes, the following function may be provided: “after accepting selection of a plurality of recipes to be compared (or selection of processing), the evaluation value is obtained in accordance with predetermined rules using all the unit-processing data for each recipe, and ranking on the recipes is performed based on the evaluation value”. In this case, as a result of ranking, a recipe ranking screen 87, for example, as shown in FIG. 26 may be displayed on the display 140. Then, at the time of determining the reference data for a certain processing, it is possible to accept selection of one or more recipes before execution of the ranking processing and take only unit-processing data, obtained by execution of the selected recipe, as targets for the ranking processing.

In addition, for example, in a case in which a plurality of substrate processing apparatuses of the same type is installed in one factory, a function of ranking on the substrate processing apparatuses for any recipe may be provided. Then, at the time of determining the reference data for the target recipe, it is possible to accept selection of the substrate processing apparatus before execution of the ranking processing and take only the unit-processing data, obtained by the selected substrate processing apparatus, as targets for the ranking processing.

Although the present invention has been described in detail above, the above description is illustrative in all aspects and is not restrictive. It is understood that numerous other modifications and variations can be devised without departing from the scope of the present invention.

The present application claims priority to Japanese Patent Application No. 2018-20799 filed on Feb. 8, 2018 entitled “Data Processing Method, Data Processing Apparatus, Data Processing System, and Data Processing Program”, and the entire contents of which are incorporated herein by reference.

What is claimed is:

1. A data processing method for processing a plurality of pieces of unit-processing data by regarding a plurality of time series data obtained by unit-processing as unit-processing data, the method comprising:
a unit-processing data evaluating step of taking, as reference data, previously defined unit-processing data among the plurality of pieces of unit-processing data and calculating an evaluation value for unit-processing data to be evaluated based on the unit-processing data to be evaluated and the reference data; and
a reference data changing step of changing the reference data based on the evaluation value calculated in the unit-processing data evaluating step.

2. The data processing method according to claim 1, wherein in the reference data changing step, ranking on a plurality of pieces of unit-processing data is performed based on the evaluation value calculated in the unit-processing data evaluating step, and the unit-processing data to be set as the reference data after change is determined based on a result of the ranking.

3. The data processing method according to claim 2, wherein the reference data changing step includes
a ranking displaying step of displaying attribute data representing attributes of the plurality of pieces of unit-processing data in a ranking format in accordance with the result of the ranking, and
a reference data selecting step of selecting attribute data of unit-processing data to be set as the reference data after change from the plurality of pieces of attribute data displayed in the ranking display step.

4. The data processing method according to claim 2, wherein in the reference data changing step, the unit-processing data ranked as the first by the ranking is defined as the reference data after change.

5. The data processing method according to claim 1, wherein the unit-processing data evaluating step includes
a data comparing step of comparing the unit-processing data to be evaluated with the reference data,
a comparison result scoring step of calculating a comparison result value that is a value obtained by scoring a comparison result obtained in the data comparing step, and
an evaluation value calculating step of calculating the evaluation value based on a plurality of index values including the comparison result value.

6. The data processing method according to claim 5, wherein in the data comparing step, each piece of time series data included in the unit-processing data to be evaluated is normalized.

7. The data processing method according to claim 1, wherein the unit-processing data evaluating step includes
a data comparing step of comparing, for a plurality of items, the unit-processing data to be evaluated with the reference data directly without processing the data value,
a comparison result value calculating step of calculating a comparison result value based on a comparison result for the plurality of items obtained in the data comparing step, and
an evaluation value calculating step of calculating the evaluation value based on a plurality of index values including the comparison result value.

8. The data processing method according to claim 5, wherein the plurality of index values include two or more index values each having a different unit.

9. The data processing method according to claim 8, wherein
the unit-processing data evaluating step includes an alarm frequency scoring step of calculating an alarm value that is a value obtained by scoring the number of occurrence of alarms generated when unit-processing corresponding to each piece of unit-processing data is executed, and
the plurality of index values include the alarm value.

10. The data processing method according to claim 8, wherein
the unit-processing data evaluating step includes a recommendation degree scoring step of calculating a recommended value that is a value obtained by scoring a recommendation degree as the reference data for each piece of unit-processing data, and
the plurality of index values includes the recommended value.

11. The data processing method according to claim 10, wherein
the unit-processing data evaluating step includes a comparison result displaying step of displaying a comparison result screen that displays a list of attribute data representing attributes of the plurality of pieces of unit-processing data and including the comparison result obtained in the data comparing step,
the attribute data displayed on the comparison result screen includes the recommendation degree, and
the comparison result screen is configured such that the recommendation degree is changeable from the outside.

12. The data processing method according to claim 8, wherein
the unit-processing data evaluating step includes a comparison result displaying step of displaying a comparison result screen that displays a list of attribute data representing attributes of the plurality of pieces of unit-processing data and including the comparison result obtained in the data comparing step,
the attribute data displayed on the comparison result screen includes freely-inputted data to which a data value for any item can be inputted,
the comparison result screen is configured such that the data value of the freely-inputted data can be changed from the outside, and
the plurality of index values includes the data value of the freely-inputted data.

13. The data processing method according to claim 5, wherein the unit-processing data evaluating step includes a contribution degree setting step of setting a contribution degree of each of the plurality of index values at the time of calculating the evaluation value.

14. The data processing method according to claim 1, wherein
the unit-processing data evaluating step includes,
a data comparing step of comparing the unit-processing data to be evaluated with the reference data to obtain a comparison result value,
a recommendation degree scoring step of calculating a recommended value that is a value obtained by scoring a recommendation degree as the reference data for each piece of unit-processing data,
an alarm frequency scoring step of calculating an alarm value that is a value obtained by scoring the number of occurrences of alarms generated when unit-processing corresponding to each piece of unit-processing data is executed,
a comparison result scoring step of calculating a comparison result value that is a value obtained by scoring a comparison result obtained in the data comparing step, and
an evaluation value calculating step of calculating the evaluation value based on a plurality of index values,
the plurality of index values includes the recommended value, the alarm value, and the comparison result value, and
the unit-processing data evaluating step further includes a contribution degree setting step of setting a contribution degree of each of the plurality of index values at the time of calculating the evaluation value.

15. The data processing method according to claim 1, wherein the evaluation value calculated in the unit-processing data evaluating step is a value obtained by comparing the unit-processing data to be evaluated with the reference data directly without processing the data value.

16. The data processing method according to claim 1, wherein the unit-processing data to be set as reference data after change by the reference data changing step is selected from one or more piece of unit-processing data obtained by unit-processing executed within a preset time period.

17. The data processing method according to claim 1, wherein
the reference data is held in a reference data storage part prepared in advance, and
in the reference data changing step, rewriting of the reference data held in the reference data storage part is performed.

18. The data processing method according to claim 1, wherein the unit-processing is processing executed as one recipe for one substrate by a substrate processing apparatus.

19. The data processing method according to claim 18, wherein the reference data is a piece of unit-processing data that is obtained when the unit-processing is first executed by the substrate processing apparatus.

20. A data processing apparatus for processing a plurality of pieces of unit-processing data by regarding a plurality of pieces of time series data obtained by unit-processing as unit-processing data, the apparatus comprising:
a unit-processing data evaluation part configured to take, as reference data, previously defined unit-processing data among the plurality of pieces of unit-processing data and calculate an evaluation value for unit-processing data to be evaluated based on the unit-processing data to be evaluated and the reference data; and
a reference data changing part configured to change the reference data based on the evaluation value calculated in the unit-processing data evaluation part.

21. A data processing system for processing a plurality of pieces of unit-processing data by regarding a plurality of pieces of time series data obtained by unit-processing as unit-processing data, the system comprising:
a unit-processing data evaluation part configured to take, as reference data, previously defined unit-processing data among the plurality of pieces of unit-processing data and calculates an evaluation value for unit-processing data to be evaluated based on the unit-processing data to be evaluated and the reference data; and
a reference data changing part configured to change the reference data based on the evaluation value calculated in the unit-processing data evaluation part.

22. A computer-readable recording medium having recorded therein a data processing program for processing a plurality of pieces of unit-processing data by regarding a plurality of time series data obtained by unit-processing as unit-processing data, wherein the data processing program causes a computer to execute:
a unit-processing data evaluating step of taking, as reference data, previously defined unit-processing data among the plurality of pieces of unit-processing data and calculating an evaluation value for unit-processing data to be evaluated based on the unit-processing data to be evaluated and the reference data; and
a reference data changing step of changing the reference data based on the evaluation value calculated in the unit-processing data evaluating step.
